(19) United States
(12) Patent Application Publication
(10) Pub. No.: US 2021/0399003 A1
(43) Pub. Date: Dec. 23, 2021

(54) THREE-DIMENSIONAL SEMICONDUCTOR MEMORY DEVICE

(71) Applicant: SAMSUNG ELECTRONICS CO., LTD., Suwon-si (KR)

(72) Inventors: Donghyun SHIN, Seoul (KR); Minkyu KANG, Bucheon-si (KR); Seorim MOON, Seoul (KR); Seunggi MIN, Suwon-si (KR); Sungmin PARK, Suwon-si (KR); Jongmin LEE, Busan (KR)

(21) Appl. No.: 17/149,967

(22) Filed: Jan. 15, 2021

(30) Foreign Application Priority Data
Jun. 17, 2020 (KR) 10-2020-0073728

(51) Int. Cl. H01L 27/11573; H01L 23/535; H01L 27/11582; H01L 21/768

(52) U.S. Cl. CPC H01L 27/11573; H01L 23/535; H01L 21/76895; H01L 21/76805; H01L 27/11582

(57) ABSTRACT

A three-dimensional semiconductor memory device includes a peripheral circuit structure, a cell array structure above the peripheral circuit structure, and peripheral contact via structures connecting the cell array structure to the peripheral circuit structure, the peripheral contact via structures including a first peripheral contact via structure in a first through region in the peripheral circuit structure, and a second peripheral contact via structure in a second through region in the peripheral circuit structure, the second through region being spaced apart from the first through region above the peripheral circuit structure, and a difference between a second critical dimension of the second peripheral contact via structure and a first critical dimension of the first peripheral contact via structure being differently configured according to material layers included in the second through region and the first through region.

### CROSS-REFERENCE TO RELATED APPLICATION

Korean Patent Application No. 10-2020-0073728, filed on Jun. 17, 2020, in the Korean Intellectual Property Office, and entitled: “Three-Dimensional Semiconductor Memory Device,” is incorporated by reference herein in its entirety.

### BACKGROUND

### 1. Field

Embodiments relate to a three-dimensional semiconductor memory device, and more particularly, to a three-dimensional semiconductor memory device with improved reliability.

### 2. Description of the Related Art

It is required to increase the degree of integration of a semiconductor memory device to satisfy excellent performance and low price demanded by consumers. In the case of a two-dimensional or planar semiconductor memory device, it is difficult to reduce an area occupied by a unit memory cell, and therefore, it is difficult to increase the degree of integration. Accordingly, three-dimensional semiconductor memory devices including three-dimensionally arranged memory cells have been proposed. It is necessary to improve the reliability of a three-dimensional semiconductor memory device.

### SUMMARY

According to an aspect of embodiments, a three-dimensional semiconductor memory device may include a peripheral circuit structure, a cell array structure above the peripheral circuit structure, and peripheral contact via structures connecting the cell array structure to the peripheral circuit structure, the peripheral contact via structures including a first peripheral contact via structure in a first through region in the peripheral circuit structure, and a second peripheral contact via structure in a second through region in the peripheral circuit structure, the second through region being spaced apart from the first through region above the peripheral circuit structure, and a difference between a second critical dimension of the second peripheral contact via structure and a first critical dimension of the first peripheral contact via structure being differently configured according to material layers included in the second through region and the first through region.

According to another aspect of embodiments, a three-dimensional semiconductor memory device may include a peripheral circuit structure, a cell array structure above the peripheral circuit structure, and peripheral contact via structures connecting the cell array structure to the peripheral circuit structure, the peripheral contact via structures including a first peripheral contact via structure in a first through region of the peripheral circuit structure, a second peripheral contact via structure in a second through region, the second through region being spaced apart from the first through region in a first direction above the peripheral circuit structure, and a third peripheral contact via structure in a third through region, the third through region being spaced apart from the first through region in a second direction, wherein the first peripheral contact via structure, the second peripheral contact via structure, and the third peripheral contact via structure respectively have a first critical dimension, a second critical dimension, and a third critical dimension, and differences between the first critical dimension, the second critical dimension, and the third critical dimension being differently configured according to material layers included in the first through region, the second through region, and the third through region.

According to yet another aspect of embodiments, a three-dimensional semiconductor memory device includes a peripheral circuit structure on a substrate, a semiconductor layer above the peripheral circuit structure, the semiconductor layer including intermediate insulating layers spaced apart from one another, a cell array structure above the semiconductor layer and the intermediate insulating layers, the cell array structure including a cell array region, an extending region at one side of the cell array region and connected to the cell array region, and a peripheral region at one side of the extending region, and peripheral contact via structures penetrating through the cell array structure and the intermediate insulating layers, and electrically connected to the peripheral circuit structure, wherein the peripheral contact via structures include a first peripheral contact via structure in a first through region, the first through region being in the extending region, a second peripheral contact via structure in a second through region, the second through region being in the peripheral region and spaced apart from the first through region in first a direction, and a third peripheral contact via structure in a third through region, the third through region being in the cell array region and spaced apart from the first through region in a second direction, and wherein the first peripheral contact via structure, the second peripheral contact via structure, and the third peripheral contact via structure respectively have a first critical dimension, a second critical dimension, and a third critical dimension, differences between the first critical dimension, the second critical dimension, and the third critical dimension being differently configured according to material layers included in the first through region, the second through region, and the third through region.

### BRIEF DESCRIPTION OF THE DRAWINGS

Features will become apparent to those of skill in the art by describing in detail exemplary embodiments with reference to the attached drawings, in which:

FIGS. 1 and 2 are circuit diagrams of a three-dimensional semiconductor memory device according to an embodiment;

FIG. 3 is a block diagram of components of a three-dimensional semiconductor memory device according to an embodiment;

FIG. 4 is a perspective view of a structure of a three-dimensional semiconductor memory device according to an embodiment;

FIG. 5 is a conceptual top-plan view of a three-dimensional semiconductor memory device according to an embodiment;

FIG. 6 is a conceptual cross-sectional view along line I-I′ in FIG. 5;

FIG. 7 is an enlarged view of portion “EN” in FIG. 6;

FIG. 8 is a conceptual cross-sectional view along line II-III′ in FIG. 5;

FIG. 9 is a conceptual cross-sectional view along line in FIG. 5;

FIG. 10 is a conceptual top-plan view of a three-dimensional semiconductor memory device according to an embodiment;

FIG. 11 is a conceptual cross-sectional view along line IV-IV′ in FIG. 10;

FIG. 12 is a conceptual cross-sectional view along line V-V in FIG. 10;

FIG. 13 is a conceptual top-plan view of a three-dimensional semiconductor memory device according to an embodiment;

FIG. 14 is a conceptual cross-sectional view along line VI-VI′ in FIG. 13;

FIGS. 15A to 15C are conceptual cross-sectional views of stages in a method of manufacturing a three-dimensional semiconductor memory device according to an embodiment;

FIG. 16 is a conceptual cross-sectional view of shapes of peripheral contact via structures in through regions of a three-dimensional semiconductor memory device according to an embodiment;

FIG. 17 is a conceptual cross-sectional view of a shape of a peripheral contact via structure in through regions of the three-dimensional memory device according to an embodiment;

FIG. 18 is a top-plan view of a mask layout for forming peripheral contact via structures of a three-dimensional semiconductor memory device according to an embodiment; and

FIG. 19 is a diagram for describing differences between critical dimensions of peripheral contact via structures according to regions in a three-dimensional semiconductor memory device according to an embodiment.

### DETAILED DESCRIPTION

Hereinafter, embodiments will be described in detail with reference to the accompanying drawings. Same reference numerals are used for same components in the drawings, and repeated description thereof will be omitted.

A three-dimensional semiconductor memory device keeps saved data even when power is not supplied. A NAND flash memory device is described as an example of the three-dimensional semiconductor memory device. Accordingly, descriptions may be directly applied to a NAND flash memory device. The three-dimensional semiconductor memory device may be referred to as a vertical non-volatile memory device.

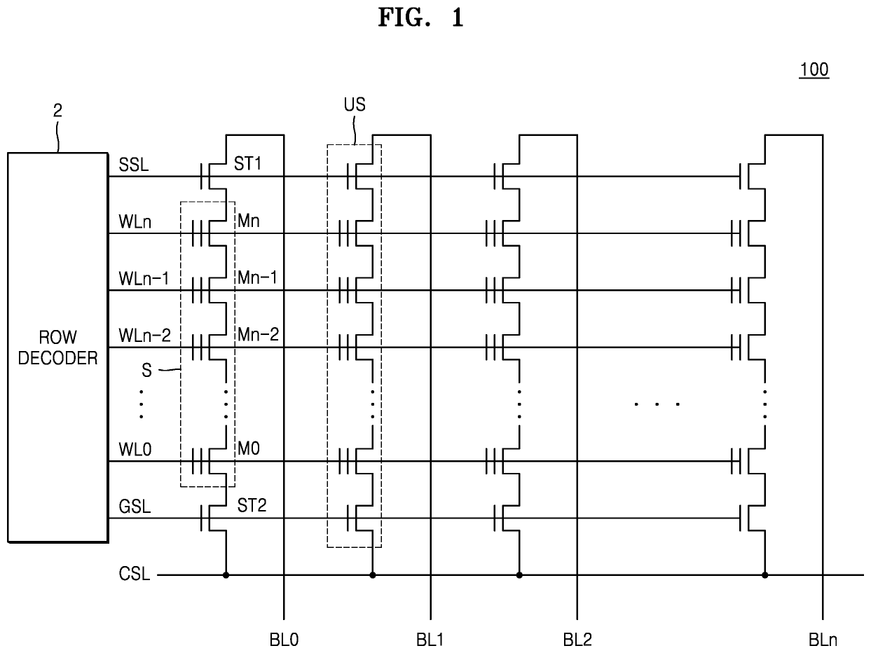

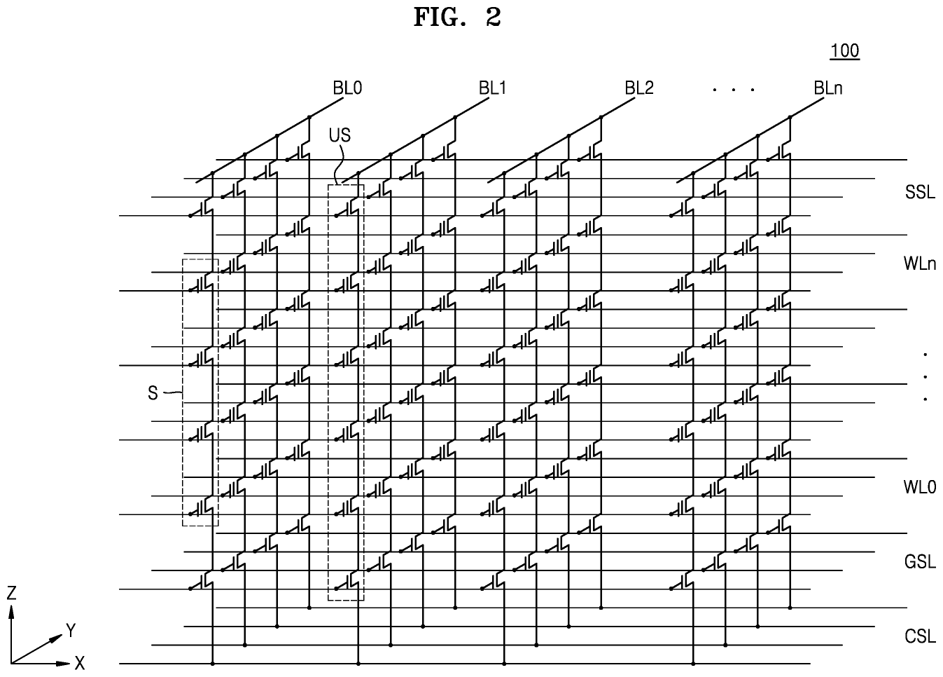

FIGS. 1 and 2 are circuit diagrams of a three-dimensional semiconductor memory device according to an embodiment.

In detail, FIGS. 1 and 2 are respectively two-dimensional and three-dimensional circuit diagrams of a three-dimensional semiconductor memory device 100, i.e., a NAND flash memory device. In the three-dimensional semiconductor memory device 100, N cell transistors M0 through Mn are connected in series and form a cell string S. The cell transistors M0 through Mn may be memory cells. Cell strings S may be connected in parallel between bit lines BL0 through BLn and a ground selecting line GSL.

The three-dimensional semiconductor memory device 100 may include the cell strings S in which the cell transistors M0 through Mn are connected in series, word lines WL0 through WLn used to select the cell transistors M0 through Mn, and a row decoder 2 configured to drive the word lines WL0 through WLn. The three-dimensional semiconductor memory device 100 may further include string selecting lines SSL connected to one side of the cell string S and connected to string selecting transistors ST1, the bit lines BL0 through BLn connected to drains of the string selecting transistors ST1, and the ground selecting line GSL connected to another side of the cell strings S and connected to ground selecting transistors ST2. Also, in the three-dimensional semiconductor memory device 100, a common source line CSL may be connected to sources of the ground selecting transistors ST2.

The three-dimensional semiconductor memory device 100 may construct a unit string US by including the cell strings S, and the string selecting transistor ST1 and the ground selecting transistor ST2 respectively connected above and below the cell strings S. Although FIGS. 1 and 2 illustrate that the unit string US is constructed by connecting one string selecting transistor ST1 and one ground selecting transistor ST2 to the cell string S, two or more string selecting transistors ST1 may be included, and two or more ground selecting transistors ST2 may be included.

A plurality of cell transistors, e.g., 2^{m} (m is a natural number equal to or greater than 1) cell transistors M0 through Mn, may be included in one cell string S. About two, four, eight, or sixteen cell transistors M0 through Mn may be connected in series to one cell string S. For convenience, FIGS. 1 and 2 show only four of the cell transistors M0 through Mn and only four of the word lines WL0 through WLn.

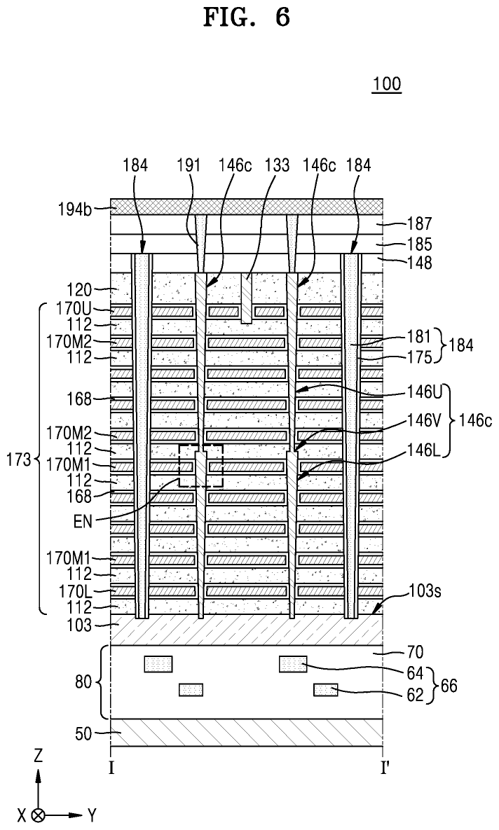

In FIG. 2, the X direction (a first direction) may be a direction in which the word lines WL0 through WLn extend, i.e., a word-line direction. The Y direction (a second direction) perpendicular to the X direction (the first direction) may be a direction in which the bit lines BL0 through BLn extend, i.e., a bit-line direction. The Z direction (a third direction) may be a direction perpendicular to a plane constructed by the word lines WL0 through WLn and the bit lines BL0 through BLn. The X direction and the Y direction may be respectively the first and second horizontal directions structurally parallel to a surface of a substrate 50 (see FIGS. 6, 8, and 9) or a surface of a semiconductor layer 103 (see FIGS. 6, 8, and 9), and the Z direction may be a vertical direction perpendicular to the surface of the substrate 50 (see FIGS. 6, 8, and 9) or the surface of the semiconductor layer 103 (see FIGS. 6, 8, and 9).

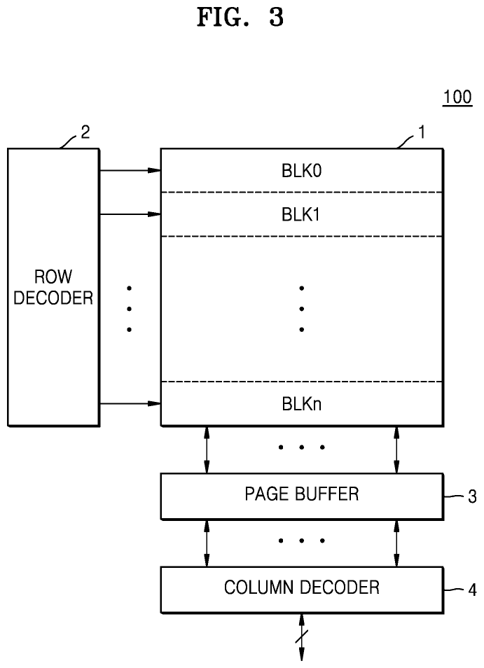

FIG. 3 is a block diagram of components of the three-dimensional semiconductor memory device 100. For example, the three-dimensional semiconductor memory device 100 may include a cell array 1 and peripheral circuits, e.g., the row decoder 2, a page buffer 3, and a column decoder 4.

The cell array 1 may be a three-dimensional cell array including the plurality of memory cells described above with reference to FIGS. 1 and 2. The cell array 1 may include, as described above, memory cells including the cell transistors M0 through Mn and the plurality of word lines WL0 through WLn and the bit lines BL0 through BLn electrically connected to the memory cells including the cell transistors M0 through Mn. In an embodiment, the cell array 1 may include a plurality of memory blocks BLK0 through BLKn that are data erasure units.

The row decoder 2 selects the word lines WL0 through WLn (see FIGS. 1 and 2) of the cell array 1. The row decoder 2 selects, according to address information, one of the memory cells BLK0 through BLKn of the cell array 1, and selects one of the word lines WL0 through WLn (see FIGS. 1 and 2) of the selected memory block (one of BLK0 through BLKn). The row decoder 2 may provide a word line voltage, which is generated from a voltage generating circuit, to the selected word line and non-selected word lines, in response to control of a control circuit.

The page buffer 3 writes information on the memory cells including the cell transistors M0 through Mn (see FIG. 1) or reads information stored in the memory cells including the cell transistors M0 through Mn (see FIG. 1). According to operation modes, the page buffer 3 may temporarily store data to be stored in the memory cells or sense the data stored in the memory cells. The page buffer 3 may operate as a write driver circuit under a program operation mode and operate as a sense amplifier circuit under a read operation mode.

The column decoder 4 may be connected to the bit lines BL0 through BLn (see FIGS. 1 and 2) of the cell array 1. The column decoder 4 may provide a data transmission path between the page buffer 3 and an external device, e.g., a memory controller.

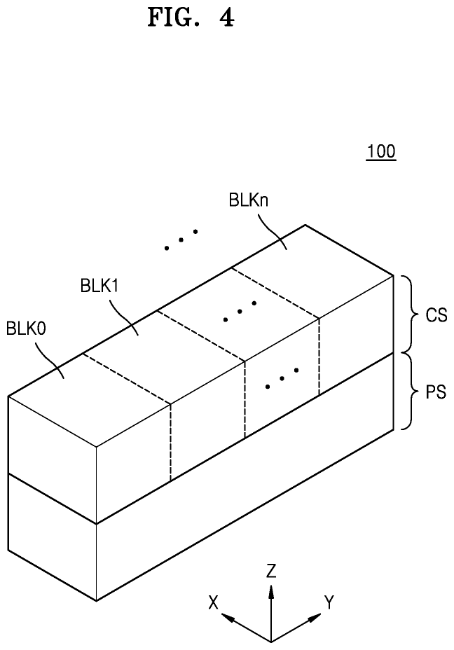

FIG. 4 is a perspective view of a structure of the three-dimensional semiconductor memory device 100. As illustrated in FIG. 4, the three-dimensional semiconductor memory device 100 may include a peripheral circuit structure PS and a cell array structure CS. The cell array structure CS may be stacked on the peripheral circuit structure PS. The peripheral circuit structure PS and the cell array structure CS may overlap in a top-plan view.

The cell array structure CS may include the cell array 1 (see FIG. 3). The cell array structure CS may include the plurality of memory blocks BLK0 through BLKn (where n is a positive integer) that are data erasure units. Each of the memory blocks BLK0 through BLKn may include the cell array 1 (see FIG. 3) having a three-dimensional structure (or a vertical structure). As described above with reference to FIGS. 1 and 2, the cell array 1 may include the memory cells including the plurality of cell transistors M0 through Mn (see FIG. 1) that are three-dimensionally arranged, and the plurality of word lines WL0 through WLn and the bit lines BL0 through BL2 electrically connected to the memory cells.

The peripheral circuit structure PS may include a peripheral circuit configured to control the cell array 1. The peripheral circuit structure PS includes at least one of the row decoder 2, the page buffer 3, and the column decoder 4, as shown in FIG. 3, and additionally, may include a control circuit configured to control the memory blocks BLK0 through BLKn.

Hereinafter, various layout diagrams of the three-dimensional semiconductor memory device 100 according to embodiments and structures thereof will be described. Embodiments of the layouts and structures described hereinafter may be used independently or in combination to implement the three-dimensional memory device. The layout diagrams described hereinafter are not used to limit embodiments, and same or similar reference numerals indicate same or similar members.

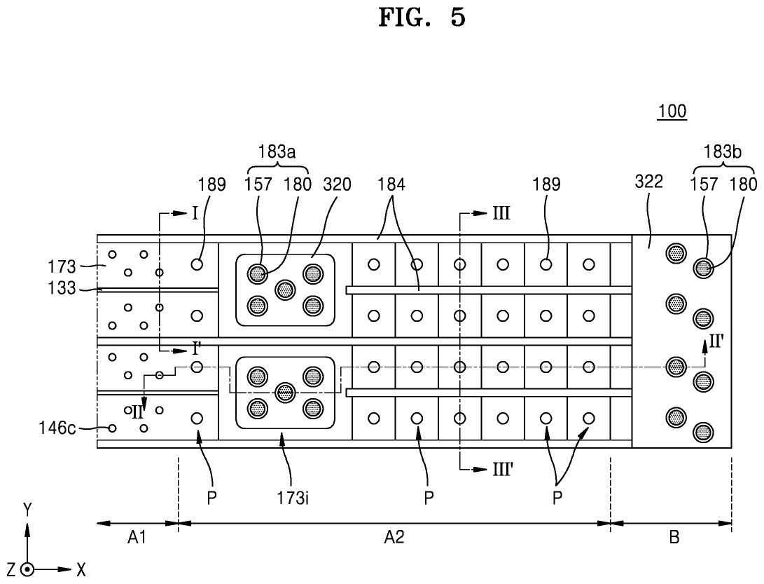

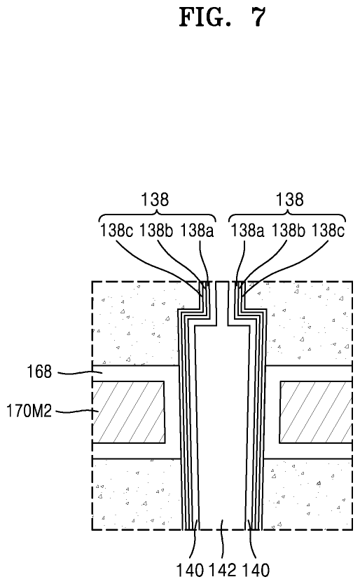

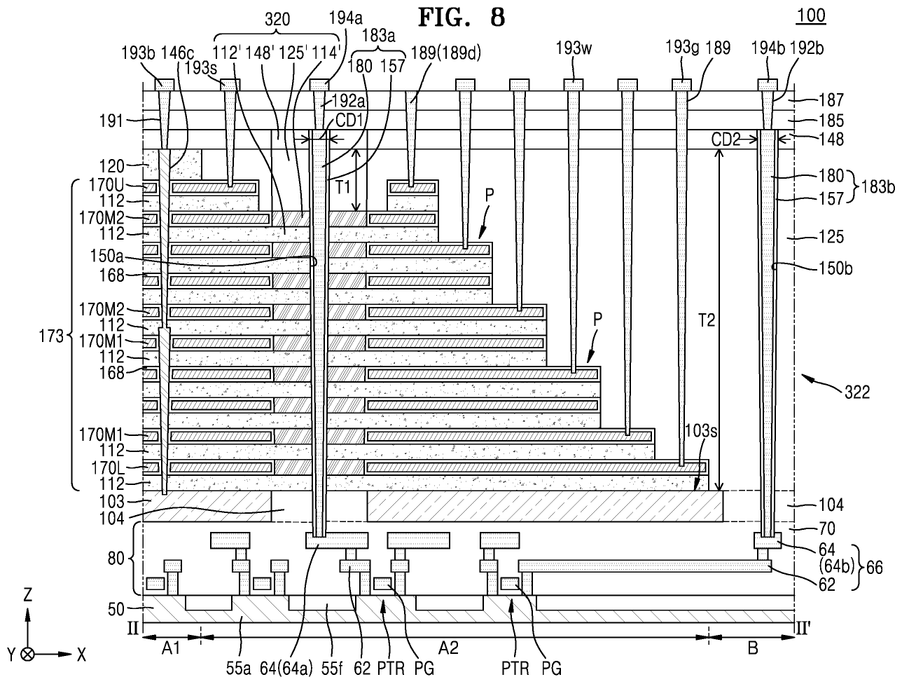

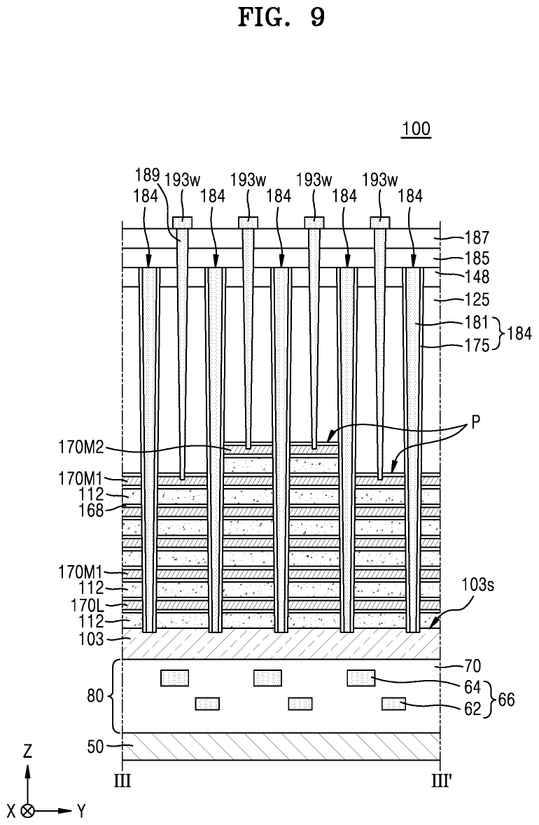

FIG. 5 is a conceptual top-plan view of the three-dimensional semiconductor memory device 100 according to an embodiment. FIG. 6 is a cross-sectional view along line I-I′ in FIG. 5, FIG. 7 is an enlarged view of portion “EN” in FIG. 6, FIG. 8 is a cross-sectional view along line II-III′ in FIG. 5, and FIG. 9 is a cross-sectional view along line in FIG. 5.

Referring to FIGS. 6 and 8-9, in the three-dimensional semiconductor memory device 100 according to an embodiment, a peripheral circuit structure 80 may be arranged on a substrate 50. The peripheral circuit structure 80 may correspond to the peripheral circuit structure PS shown in FIG. 4. The substrate 50 may include a semiconductor substrate that may include a semiconductor material, e.g., silicon. The substrate 50 may be referred to as a lower substrate. For example, the substrate 50 may include a monocrystalline silicon substrate. The peripheral circuit structure 80 may include at least one of the row decoder 2, the page buffer 3, and the column decoder 4 described with reference to FIG. 3.

In addition, the peripheral circuit structure 80 may include peripheral transistors PTR, a peripheral wiring structure 66 that may be electrically connected to the peripheral transistors PRT, and a lower insulating layer 70 covering the peripheral transistors PTR and the peripheral wiring structure 66. The lower insulating layer 70 may include, e.g., a silicon oxide layer. The peripheral transistors PTR may include active regions 55a, which may be defined by field regions 55f on the substrate 50, and peripheral gates PG formed above the active regions 55a. The peripheral wiring structure 66 may include lower peripheral wirings 62 and upper peripheral wirings 64 above the lower peripheral wirings 62.

The upper peripheral wirings 64 and the lower peripheral wirings 62 may include a metallic material, e.g., tungsten or copper. In some embodiments, the upper peripheral wirings 64 may have a thickness greater than that of the lower peripheral wirings 62.

A semiconductor layer 103 may be arranged on the peripheral circuit structure 80. In some embodiments, the semiconductor layer 103 may include, e.g., a silicon layer or a polysilicon layer. In some embodiments, the semiconductor layer 103 may be referred to as an upper substrate. The semiconductor layer 103 may include a plurality of intermediate insulating layers 104 spaced apart from one another, e.g., in the X direction. The intermediate insulating layers 104 may be formed by patterning the semiconductor layer 103 to form openings and then by filling insulating layers in the openings. The intermediate insulating layers 104 may include, e.g., silicon oxide.

A stack structure 173 may be arranged on the semiconductor layer 103 and the intermediate insulating layers 104. The stack structure 173 may include gate horizontal patterns 170L, 170M1, 170M2, and 170U. The gate horizontal patterns 170L, 170M1, 170M2, and 170U may include pad regions P that are stacked apart from one another in the vertical direction Z in the first region A1 and extending in the first horizontal direction X from the first region A1 into the second region A2 and then arranged in a steps shape. The pad regions P are not limited to the steps shape shown in the drawing and may be modified into various shapes.

The vertical direction Z may be a direction perpendicular to a top surface 103s of the semiconductor layer 103, and the first horizontal direction X may be a direction parallel or horizontal to the top surface 103s of the semiconductor layer 103. In some embodiments, the first region A1 may be a cell array region in which the cell array 1 described with reference to FIGS. 2 and 3 is located.

In some embodiments, the second region A2 may be at one side or two sides, e.g., ion the X direction, of the first region A1. For example, the second region A2 may be at the right side and the left side of the first region A1. The second region A2 may be a region in which the gate horizontal patterns 170L, 170M1, 170M2, and 170U extend from the first region A1 and the pad regions P are formed. The second region A2 may be an extending region electrically connected to the cell array region (i.e., the first region A1). A third region B of the semiconductor layer 103, in which the gate horizontal patterns 170L, 170M1, 170M2, and 170U are not formed, may be referred to as a peripheral region.

The gate horizontal patterns 170L, 170M1, 170M2, and 170U may include a lower gate horizontal pattern 170L, an upper gate horizontal pattern 170U on the lower gate horizontal pattern 170L, and middle gate horizontal patterns 170M1 and 170M2 between the lower gate horizontal pattern 170L and the upper gate horizontal pattern 170U. For convenience, FIG. 8 shows the middle gate horizontal patterns 170M1 and 170M2 as stacked in four. However, according to necessity, the middle gate horizontal patterns 170M1 and 170M2 may be stacked in dozens or hundreds.

The gate horizontal patterns 170L, 170M1, 170M2, and 170U may be arranged in the first region A1 and extend from the first region A1 into the second region A2. The pad regions P may be defined as regions that do not overlap with the gate horizontal patterns located at a relatively higher portion of the gate horizontal patterns 170L, 170M1, 170M2, and 170U.

In some embodiments, as seen in the first horizontal direction X in FIG. 8, the pad regions P may be configured in a shape in which a plurality of steps are sequentially arranged away from, while being apart from, the first region A1. As seen in the second horizontal direction Y in FIG. 9, the pad regions P may be configured in a shape in which steps are arranged at two sides with reference to any one of separating structures 184. The second horizontal direction Y may be parallel or horizontal to the top surface 103s of the semiconductor layer 103 and perpendicular to the first horizontal direction X. The pad regions P are not limited to the steps shape shown in FIGS. 8 and 9, and may be modified and arranged in various shapes.

The middle gate horizontal patterns 170M1 and 170M2 may include first middle gate horizontal patterns 170M1 and second middle horizontal patterns 170M2 above the first middle gate horizontal patterns 170M1. In some embodiments, as shown in FIG. 8, in middle portions of the middle gate horizontal patterns 170M1 and 170M2, i.e., in portions in which the first middle gate horizontal patterns 170M1 and the second middle gate horizontal patterns 170M2 contact each other, widths in the first horizontal directions X are differently configured, but may also be configured the same. In the first region A1 and the second region A2, the upper gate horizontal patterns 170U may be separated in the second horizontal direction (Y direction) by an insulating pattern 133. The insulating pattern 133 may include, e.g., silicon oxide.

The gate horizontal patterns 170L, 170M1, 170M2, and 170U may include gate electrodes. The lower gate horizontal pattern 170L may be the ground selecting line GSL described with reference to FIG. 2. The upper gate horizontal pattern 170U may be the string selecting line SSL described with reference to FIG. 2. In some embodiments, the middle gate horizontal patterns 170M1 and 170M2 may be the word lines WL described with reference to FIGS. 1 and 2.

The stack structure 173 may include interlayer insulating layers 112. The interlayer insulating layers 112 may be repeatedly stacked in alternating shift with the gate horizontal patterns 170L, 170M1, 170M2, and 170U. For example, the interlayer insulating layers 112 may be arranged under the gate horizontal patterns 170L, 170M1, 170M2, and 170U, respectively. The interlayer insulating layers 112 may include, e.g., silicon oxide.

A first upper insulating layer 120 and second upper insulating layers 125 and 125′ may be arranged in the first region A1, the second region A2, and the third region B. The first upper insulating layer 120 and the second upper insulating layers 125 and 125′ may include, e.g., silicon oxide. Top surfaces of the first and second upper insulating layers 120, 125, and 125′ may be on a same plane.

The first upper insulating layer 120 may be arranged in the first region, and the second upper insulating layers 125 and 125′ may be arranged in regions other than the first region A1, i.e., in the second region A2 and the third region B. The stack structure 173 in the first region A1 may be covered by the first upper insulating layer 120, and the stack structure 173 in the second region A2 may be covered by the second upper insulating layers 125 and 125′. The third region B may be covered with only the second upper insulating layer 125.

As illustrated in FIGS. 5 and 8, a first through region 320 including the second upper insulating layer 125′ and mold structures 112′ and 114′ may be arranged in the second region A2. In a broad sense, the first through region 320 may include the intermediate insulating layer 104. The mold structures 112′ and 114′ may be an interlayer insulating layer 112′ and a mold insulating layer 114′, respectively (e.g., the mold structure 112′ and the interlayer insulating layer 112′ may be used interchangeably, and the mold structure 114′ and the mold insulating layer 114′ may be used interchangeably). A first peripheral contact via structure 183a in the first through region 320 may penetrate through the second upper insulating layer 125′, the mold structures 112′ and 114′, and the intermediate insulating layer 104, and may extend in the vertical direction Z. The first through region 320 may include, e.g., silicon oxide. A thickness of the second upper insulating layer 125′ in the first through region 320 may be T1.

A plurality of capping insulating layers may be arranged on the first and second upper insulating layers 120, 125, and 125′. The plurality of capping insulating layers may include first capping insulating layers 148 and 148′, a second capping insulating layer 185, and a third capping insulating layer 187. Each of the first through third capping insulating layers 148, 148′, 185, and 187 may include an oxide-based insulating material, e.g., silicon oxide. In a broad sense, the first through region 320 may include the interlayer insulating layer 112′, the mold insulating layer 114′, the second upper insulating layer 125′, and the first capping insulating layer 148′.

Vertical channel structures 146c penetrating through the stack structure 173 may be arranged in the first region A1. The vertical channel structure 146c may penetrate through the stack structure 173 and the first upper insulating layer 120 in the vertical direction Z.

The first peripheral contact via structure 183a may be arranged on a first peripheral pad portion 64a of the upper peripheral wiring 64. The first peripheral contact via structure 183a arranged in the first through region 320 may contact the first peripheral pad portion 64a of the upper peripheral wiring 64, extend in the vertical direction Z, and sequentially penetrate through the lower insulating layer 70, the semiconductor layer 103, the mold structures 112′ and 114′, the second upper insulating layer 125′, and the first capping insulating layer 148′.

As illustrated in FIG. 5, a second through region 322 including the second upper insulating layer 125 may be arranged in the third region B. The second through region 322 may be arranged apart from the first penetrating region 320 in the first horizontal direction, e.g., along the X direction. As illustrated in FIG. 8, a second peripheral contact via structure 183b arranged in the second through region 322 may penetrate through the second upper insulating layer 125 and the interlayer insulating layer 104 in the vertical direction Z. A thickness of the second upper insulating layer 125 in the second through region 322 may be T2 that is greater than T1. The second through region 322 may include, e.g., silicon oxide.

As described above, the second peripheral contact via structure 183b may be arranged in the second through region 322. The second peripheral contact via structure 183b may be arranged on the second peripheral pad portion 64b of the upper peripheral wiring 64. The second peripheral contact via structure 183b may contact the second peripheral pad portion 64b of the upper peripheral wiring 64, extend in the vertical direction Z, and sequentially penetrate through the lower insulating layer 70, the intermediate insulating layer 104, the second upper insulating layer 125, and the first capping insulating layer 148.

The first peripheral contact via structure 183a and the second peripheral contact via structure 183b may have identical cross-section structures and identical plane shapes. For example, the first peripheral contact via structure 183a and the second peripheral contact via structure 183b may each include a through via 180 and a contact spacer 157 surrounding a side of the through via 180. The through via 180 may include a conductive pillar. The through via 180 may include metal nitride, e.g., titanium nitride (TiN) and/or metal, e.g., tungsten. The contact spacer 157 may include, e.g., silicon oxide.

Top surfaces of the first peripheral contact via structure 183a and the second peripheral contact via structure 183b may be on a same plane. Top surfaces of the first peripheral contact via structure 183a and the second peripheral contact via structure 183b may be at a same height from the top surface 103s of the semiconductor layer 103.

The first peripheral contact via structure 183a may be in a first peripheral contact hole 150a. The first peripheral contact hole 150a may be formed by selectively etching the first capping insulating layer 148′ and the second upper insulating layer 125′ included in the first through region 320, the intermediate insulating layer 104, and the lower insulating layer 70. The second peripheral contact via structure 183b may be in a second peripheral contact hole 150b. The second peripheral contact hole 150b may be formed by selectively etching the first capping insulating layer 148 and the second upper insulating layer 125 included in the second through region 322, the intermediate insulating layer 104, and the lower insulating layer 70.

In a manufacturing process, the first peripheral contact hole 150a and the second peripheral contact hole 153b may be simultaneously formed. In embodiments, a skew, which is defined by a difference between critical dimensions of the first peripheral contact via structure 183a and the second peripheral contact via structure 183b respectively formed in the first peripheral contact hole 150a and the second peripheral contact hole 153b, is differently configured according to material layers included in the first through region 320 and the second through region 322. For example, since the first peripheral contact hole 150a and the second peripheral contact hole 153b are formed through combinations of different layers that have a same total thickness, the first peripheral contact hole 150a and the second peripheral contact hole 153b may be formed simultaneously to have different widths, e.g., via holes having different diameters, in order to increase stability of each of the first peripheral contact hole 150a and the second peripheral contact hole 153b through their respective layers.

In other words, in embodiments, the skew is defined by a difference between a second critical dimension CD2 of the second peripheral contact via structure 183b and a first critical dimension CD1 of the first peripheral contact via structure 183a, and the skew is adjusted to be 10% or lower based on the first critical dimension CD1 or the second critical dimension CD2. For example, the difference between the second critical dimension CD2 of the second peripheral contact via structure 183b and the first critical dimension CD1 of the first peripheral contact via structure 183a may be adjusted to be 10% or lower. By doing so, the reliability of the three-dimensional semiconductor memory device 100 may be improved. The critical dimension will be described in more detail later.

The vertical channel structures 146c penetrating through the stack structure 173 may be arranged in the first region A1. As illustrated in FIG. 6, the vertical channel structure 146c may include a lower vertical region 146L, an upper vertical region 146U above the lower vertical region 146L, and a width variation region 146V between the lower vertical region 146L and the upper vertical region 146U.

Each of the lower vertical region 146L and the upper vertical region 146U may have an increasing width, e.g., in the Y direction, as a distance from the top surface 103s of the upper substrate 103 increases in the vertical direction Z. Accordingly, an upper region of the lower vertical region 146L may have a width greater than that of a lower region of the upper vertical region 146U. The width variation region 146V may be a region changing from a relatively greater width of a top portion of the lower vertical region 146L to a relatively smaller width of a bottom portion of the upper vertical region 146U.

As illustrated in FIGS. 6 and 7, the vertical channel structure 146c may include a channel semiconductor layer 140 and a gate dielectric structure 138 between the channel semiconductor layer 140 and the stack structure 173. The gate dielectric structure 138 may include a tunnel dielectric layer 138a, an information storage layer 138b, and a blocking dielectric layer 138c. The tunnel dielectric layer 138a may include, e.g., silicon oxide and/or silicon oxide doped with an impurity. The blocking dielectric layer 138c may include, e.g., silicon oxide and/or a high dielectric material. The information storage layer 138b may include a material capable of storing information, e.g., silicon nitride.

The vertical channel structures 146c may penetrate through the stack structure 173 in the vertical direction Z to penetrate through the first upper insulating layer 120. Separating structures 184 may be arranged on the semiconductor layer 103. In some embodiments, the separating structures 184 may penetrate through the stack structure 173.

In the first region A1, the separating structures 184 may penetrate through the stack structure 173, extend in the vertical direction Z, and penetrate through the first upper insulating layer 120 and the first capping insulating layer 148. The separating structures 184 may extend in the first horizontal direction X and separate the stack structure 173 in the second horizontal direction Y.

Between the separating structures 184 crossing the first region A1 and the second region A2, the stack structure 173 is not completely cut by the first through region 320 in the second region A2 and may be continuously connected through a connecting region 173i around the first through region 320 (FIG. 5). For example, the gate horizontal patterns having pad regions in the second region A2, i.e., the first and second middle gate horizontal gate patterns 170M1 and 170M2 and the lower gate horizontal pattern 170L, may continuously extend from the pad regions P around the first through region 320, i.e., the connecting region 173i, into the first region A1.

Each of the separating structures 184 may include a separating core pattern 181 and a separating spacer 175 on a side surface of the separating core pattern 181. The separating core pattern 181 may include a conductive material. In an embodiment, the separating core pattern 181 may be the common source line. The separating spacer 175 may include an insulating material, e.g., silicon oxide.

The stack structure 173 may include a dielectric layer 168 that may cover top surfaces and bottom surfaces of the gate horizontal patterns 170L, 170M1, 170M2, and 170U, and extend to some side surfaces of the gate horizontal patterns 170L, 170M1, 170M2, and 170U. The dielectric layer 168 may include a high-k electric, e.g., aluminum oxide.

Bit line contact plugs 191 on the vertical channel structures 146c, gate contact plugs 189 on the pad regions P of the gate horizontal patterns 170L, 170M1, 170M2, and 170U, a first peripheral contact plug 192a on the first peripheral contact via structure 183a, and a second peripheral contact plug 192b on the second peripheral contact via structure 183b may be arranged. Bit lines 193b, a string selecting gate connecting wiring 193s, word line connecting wirings 193w, ground selecting gate connecting wiring 193, a first peripheral connecting wiring 194a, and a second peripheral connecting wiring 194b may be arranged on the third capping insulating layer 187.

The bit lines 193b may be electrically connected to the vertical channel structures 146c via the bit line contact plugs 191. The string selecting gate connecting wiring 193s may be electrically connected to the upper gate horizontal pattern 170U via a gate contact plug 189 on the pad region P of the upper gate horizontal pattern 170U.

The word line connecting wirings 193w may be electrically connected to the first and second middle gate horizontal patterns 170M1 and 170M2 via the gate contact plugs 189 above the first and second middle gate horizontal patterns 170M1 and 170M2. The ground selecting gate connecting wiring 193g may be electrically connected to the lower gate horizontal pattern 170L via the gate contact plug 189 on the pad region P of the lower gate horizontal pattern 170L. In some embodiments, the gate contact plug 189 connected to the upper gate horizontal pattern 170U may be a dummy gate contact plug 189d.

The first peripheral connecting wiring 194a may be connected to the string selecting line connecting wiring 193s and at least some of the word line connecting wirings 193w. The second peripheral connecting wirings 194b may be connected to the ground selecting line connecting wiring 193g and at least some of the word line connecting wirings 193w. The word line connecting wirings 193w may be connected to the peripheral circuit structures 80 via the first peripheral connecting wiring 194a and the second peripheral connecting wiring 194b.

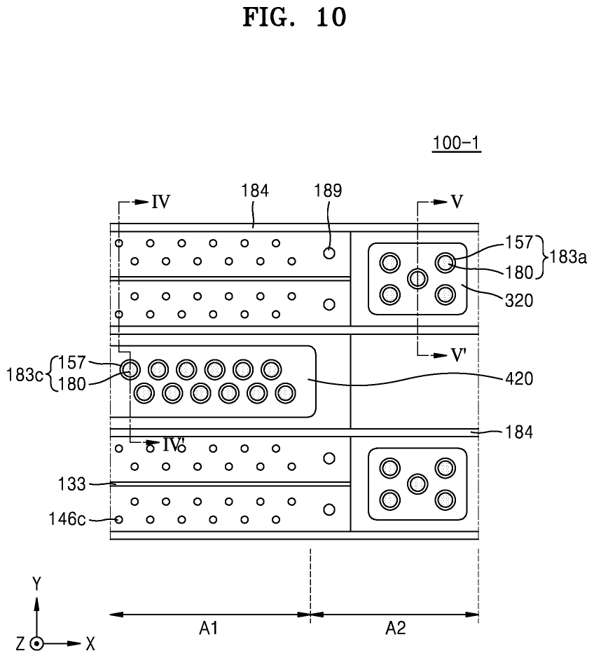

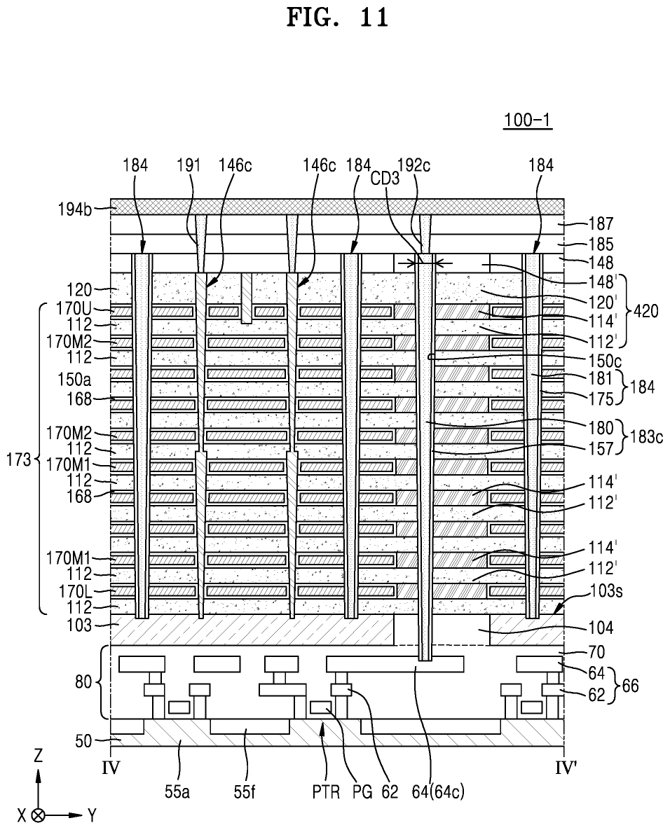

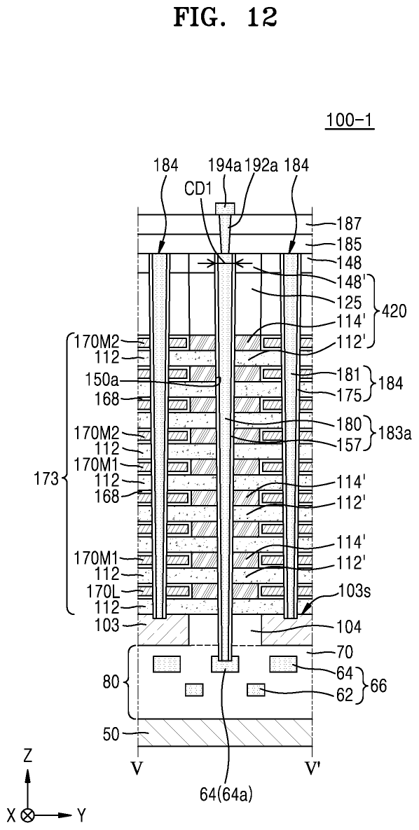

FIG. 10 is a conceptual top-plan view of a three-dimensional semiconductor memory device according to an embodiment. FIG. 11 is a cross-sectional view along line IV-IV′ in FIG. 10, and FIG. 12 is a cross-sectional view along line V-V in FIG. 10.

In detail, a three-dimensional semiconductor memory device 100-1 may be identical to the three-dimensional semiconductor memory device 100 shown in FIGS. 5 through 9, except that the three-dimensional semiconductor memory device 100-1 further includes a third through region 420 in the first region A1. In FIGS. 10 through 12, elements described previously with reference to FIGS. 5 through 9 will be only briefly described or omitted.

Referring to FIGS. 10-12, in the three-dimensional semiconductor memory device 100-1, the third through region 420 may be arranged in the first region A1. The third through region 420 may include the first upper insulating layer 120′, the mold structures 112′ and 114′, and the intermediate insulating layer 104. In a broad sense, the third through region 420 may include the first capping insulating layer 148′.

A third peripheral contact via structure 183c may be arranged in the third through region 420. The third peripheral contact via structure 183c may be arranged above a third peripheral pad portion 64c of the upper peripheral wiring 64. The third peripheral contact via structure 183c may contact the third peripheral pad portion 64c of the upper peripheral wiring 64, extend in the vertical direction Z, and may sequentially penetrate through the lower insulating layer 70, the intermediate insulating layer 104, the first upper insulating layer 102′, and the first capping insulating layer 148′.

As described above, the first through region 320 may be arranged in the second region A2. The first through region 320, in the second region A2, may penetrate through the second upper insulating layer 125′, the mold structures 112′ and 114′, and the intermediate insulating layer 104 and extend in the vertical direction. The mold structures 112′ and 114′ in both the first and third through regions 320 and 420 may include the interlayer insulating layer 112′ and the mold insulating layer 114′.

The first peripheral contact via structure 183a may be arranged in the first through region 320. The first peripheral contact via structure 183a may contact the first peripheral pad portion 64a of the upper peripheral wiring 64, extend in the vertical direction Z, and may sequentially penetrate through the lower insulating layer 70, the intermediate insulating layer 104, the mold structure 112′ and 114′, the second upper insulating layer 125′, and the first capping insulating layer 148′.

Top surfaces of the third peripheral contact via structure 183 and the first peripheral contact via structure 183a may be on a same plane. The top surfaces of the third peripheral contact via structure 183c and the first peripheral contact via structure 183a may be at a same height from the top surface 103s of the semiconductor layer 103.

The third peripheral contact via structure 183c may be in a third peripheral contact hole 150c. The third peripheral contact hole 150c may be formed by selectively etching the first capping insulating layer 148′ and the first upper insulating layer 120′, and the mold structure 112′ and 114′ included in the third through region 420, and the intermediate insulating layer 104 and the lower insulating layer 170.

As described above, the first peripheral contact via structure 183a may be in the first peripheral contact hole 150a. The first peripheral contact hole 150a may be formed by selectively etching the first capping insulating layer 148′, the second upper insulating layer 125′, and the mold structure 112′ and 114′, and the intermediate insulating layer 104 and the lower insulating layer 70.

In a manufacturing process, the third peripheral contact hole 150c and the first peripheral contact hole 150a may be simultaneously formed. In embodiments, a skew, which is defined by a difference between critical dimensions of the third peripheral contact via structure 183c and the first peripheral contact via structure 183a respectively formed in the third peripheral contact hole 150c and the first peripheral contact hole 153a, is differently configured according to material players included in the third through region 420 and the first through region 320.

In other words, in embodiments, the skew defined by a difference between a third critical dimension CD3 of the third peripheral contact via structure 183c and the first critical dimension CD1 of the first peripheral contact via structure 183a is adjusted to be 10% or smaller with reference to the first critical dimension CD1 or the third critical dimension CD3. By doing so, the reliability of the three-dimensional semiconductor memory device 100-1 may be improved.

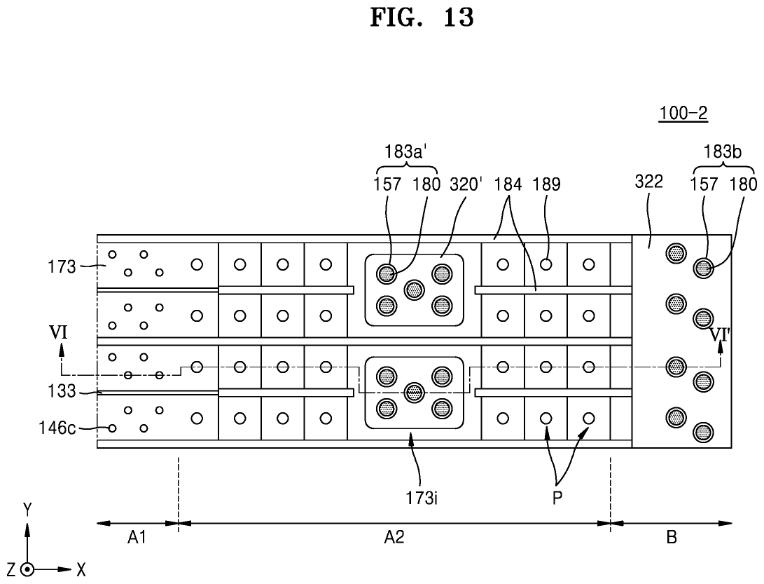

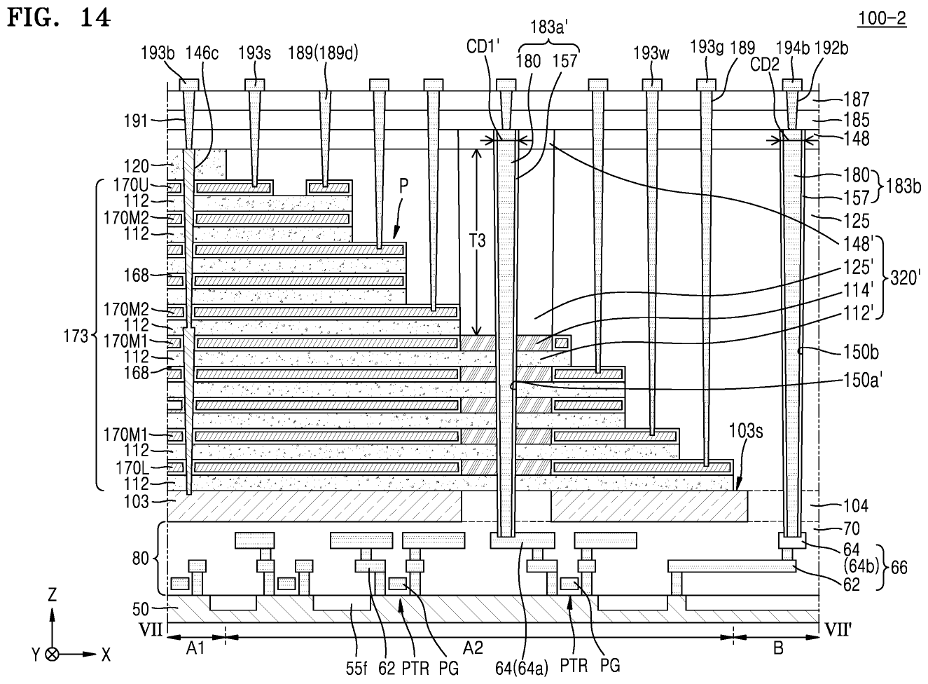

FIG. 13 is a top-plan view of a three-dimensional memory device according to an embodiment. FIG. 14 is a cross-sectional view along line VI-VI′ of FIG. 13.

In detail, a three-dimensional semiconductor memory device 100-2 may be identical to the three-dimensional semiconductor memory device 100 shown in FIGS. 5 through 9, except a first through region 320′ is formed in the first horizontal direction (the X direction) in a middle portion of the second region A2 of the three-dimensional semiconductor memory device 100-2. In FIGS. 13 and 14, elements previously described with reference to FIGS. 5 through 9 will be only briefly described or omitted.

Referring to FIGS. 13 and 14, in the three-dimensional semiconductor memory device 100-2, the first through region 320′ may be arranged in a middle portion of the second region A2 in the first horizontal direction (the X direction). The first through region 320′ may include the second upper insulating layer 125′ and the mold structure 112′ and 114′. In a broad sense, the first through region 320′ may include the intermediate insulating layer 104. A thickness of the second upper insulating layer 125′ in the first through region 320′ may be T3.

The thickness T3 of the second upper insulating layer 125′ may be greater than the thickness T1 of the second upper insulating layer 125′ in the first through region 320 in FIG. 8 and smaller than the thickness T2 of the second through region 322 in FIG. 8. The thickness T3 of the second upper insulating layer 125′ may change according to a position of the first through region 320′ in the second region A2 in the first horizontal direction (the X direction). The mold structures 112′ and 114′ may include the interlayer insulating layer 112′ and the mold insulating layer 114′. In a broad sense, the first through region 320′ may be a region penetrating through the first capping insulating layer 148′.

The first peripheral contact via structure 183a′ may be arranged in the first through region 320′. The first peripheral contact via structure 183a′ may be arranged above the first peripheral pad portion 64a of the upper peripheral wiring 64. The first peripheral contact via structure 183a′ may contact the first peripheral pad portion 64a of the upper peripheral wiring 64, extend in the vertical direction Z, and sequentially penetrate through the lower insulating layer 70, the intermediate insulating layer 104, the mold structures 112′ and 114′, the first upper insulating layer 125′, and the first capping insulating layer 148′.

As described above, the second through region 322 may be arranged in the third region B. The second peripheral contact via structure 183b in the second through region 322 may penetrate through the second upper insulating layer 125 in the vertical direction in the third region B.

The second peripheral contact via structure 183b may be arranged in the second through region 322. The second peripheral contact via structure 183b may contact the second peripheral pad portion 64b of the upper peripheral wiring 64, extend in the vertical direction Z, and sequentially penetrate through the lower insulating layer 70, the intermediate insulating layer 104, the second upper insulating layer 125, and the first capping insulating layer 148.

Top surfaces of the first peripheral contact via structure 183a′ and the second peripheral contact via structure 183b may be on a same plane. Top surfaces of the first peripheral contact via structure 183′ and the second peripheral contact via structure 183b may be at a same height from the top surface 103s of the semiconductor layer 103.

The first peripheral contact via structure 183a′ may be in a first peripheral contact hole 150a′. The second peripheral contact hole 150b may be formed by selectively etching the first capping insulating layer 148′, the second upper insulating layer 125, the intermediate insulating layer 104, and the lower insulating layer 70 included in the second through region 322.

As described above, the first peripheral contact via structure 183a′ may be in the first peripheral contact hole 150a′. The first peripheral contact hole 150′ may be formed by selectively etching the first capping insulating layer 148′, the second upper insulating layer 125′, and the mold structure 112′ and 114′ included in the first through region 320, and the intermediate insulating layer 104 and the lower insulating layer 70.

In a manufacturing process, the first peripheral contact hole 150a′ and the second peripheral contact hole 150b may be simultaneously formed. In embodiments, a skew, which is defined by a difference between critical dimensions of the first peripheral contact via structure 183a′ and the second peripheral contact via structure 183b respectively formed in the first peripheral contact hole 150a′ and the second peripheral contact hole 150b, is differently configured according to material layers included in the first through region 320′ and the second through region 322.

In other words, in embodiments, the skew defined by a difference between a critical dimension CD1′ of the first peripheral contact via structure 183′ and the second critical dimension CD2 of the second peripheral contact via structure 183b is adjusted to be 10% or smaller based on the first critical dimension CD1 or the second critical dimension CD2. By doing so, the reliability of the three-dimensional semiconductor memory device 100-2 may be improved.

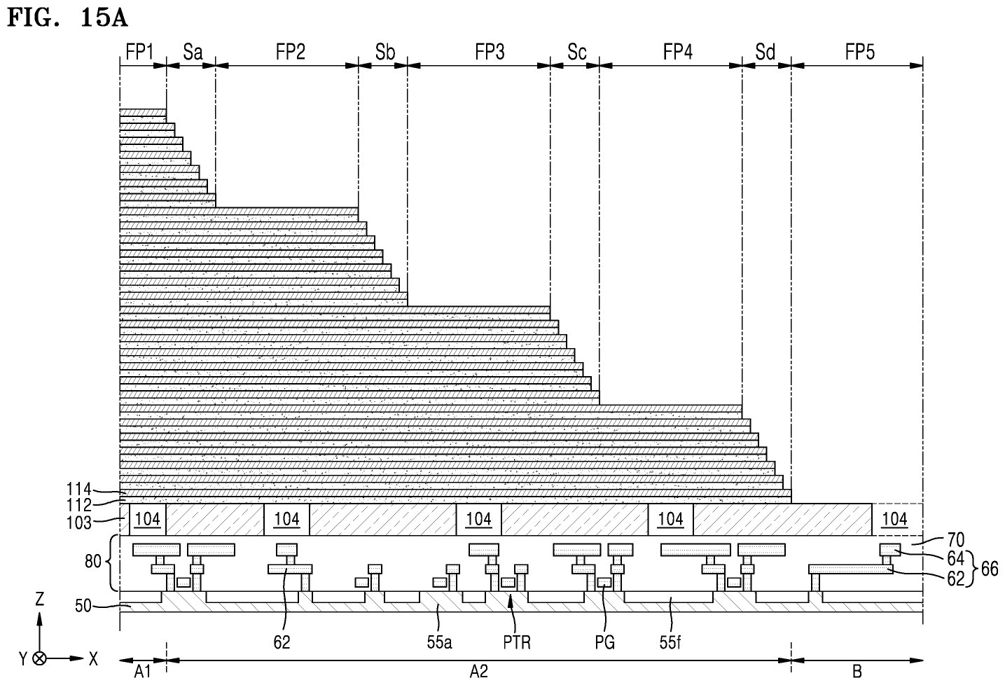

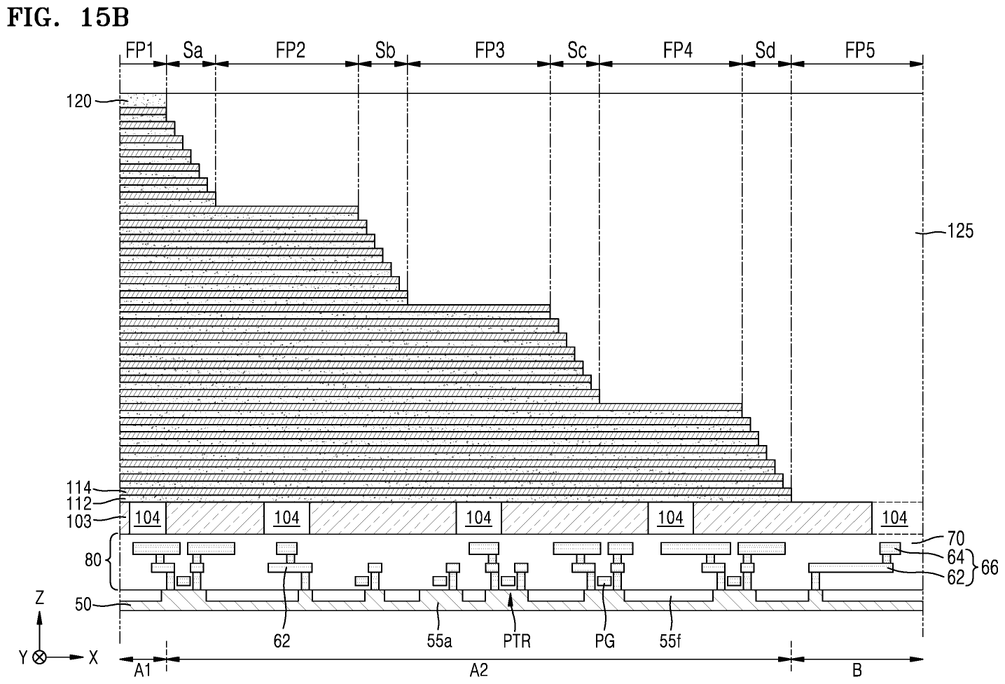

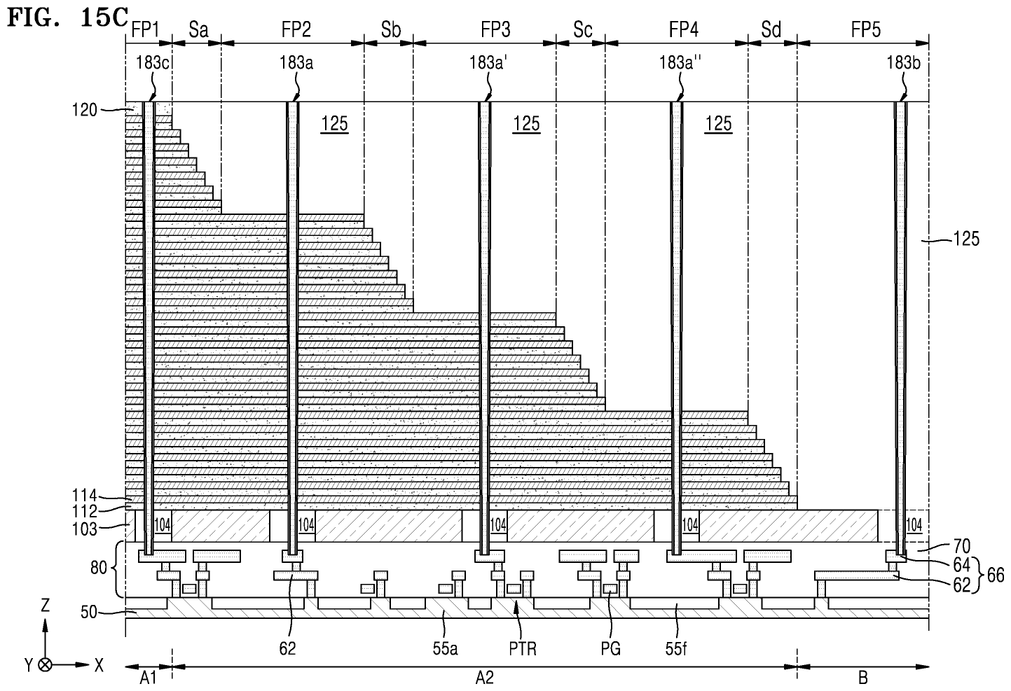

FIGS. 15A through 15C are conceptual cross-sectional views of stages in a method of manufacturing a three-dimensional semiconductor memory device according to an embodiment. In detail, FIGS. 15A through 15C are stages in a method of forming the peripheral contact via structures 183a, 183a′, 183a″, 183b, and 183c, and for convenience, the vertical channel structures and the like are not shown.

Referring to FIG. 15A, the peripheral circuit structure 80 is formed on the substrate 50. The substrate 50 may include the first region A1, the second region A2, and the third region B. The first region A1 may be a cell array region, in which the cell array described above is located. The second region A2 may be an extending region electrically connected to the cell array region (i.e., connected to the first region A1). The third region B may be a peripheral region located at one side of the second region A2, e.g., the second region A2 may be between the first region A1 and the third region B along the X direction.

As described above, the substrate 50 may include the active regions 55a defined by the field regions 55f, the peripheral gates PG, and the peripheral transistors PTR. The semiconductor layer 103 and the intermediate insulating layers 104 are formed on the peripheral circuit structure 80. As described above, the intermediate insulating layers 104 may be formed by patterning the semiconductor layer 103 to form openings and filling insulating layers in the openings. The intermediate insulating layers 104 may include, e.g., silicon oxide.

A plurality of interlayer insulating layers 112 and mold insulating layers 114 are sequentially deposited on the semiconductor layer 103 and the intermediate insulating layer 104, and patterned to form a plurality of flat structures FP1, FP2, FP3, FP4, and FP5 and a plurality of step-type structures Sa, Sb, Sc, and Sd. Widths of the flat structures FP1, FP2, FP3, FP4, and FP5 are identical to one another in the first horizontal direction (the X direction). Each of the flat structures FP1, FP2, FP3, FP4, and FP5 has a same width even when the flat structures FP1, FP2, FP3, FP4, and FP5 become apart from one another on the peripheral circuit structure 80. Widths of step-type structures Sa, Sb, Sc, and Sd decrease in the first horizontal direction (the X direction) away from the peripheral circuit structure 80. In the second area A2, the flat structures FP2, FP3, and FP4 may be located between the step-type structures Sa, Sb, Sc, and Sd. Although the numbers of flat structures FP1, FP2, FP3, FP4, and FP5 and step-type structures Sa, Sb, Sc, and Sd may be large, only five flat structures FP1, FP2, FP3, FP4, and FP5 and four step-type structures Sa, Sb, Sc, and Sd are shown.

Referring to FIG. 15B, the first upper insulating layer 120 and the second upper insulating layer 125 are formed on the step-type structures Sa, Sb, Sc, and Sd and the flat structures FP1, FP2, FP3, FP4, and FP5 of the first region A1, the second region A2, and the third region B. The flat structures FP1 of the first region A1 may be covered by the first upper insulating layer 120, and the flat structures FP2, FP3, FP4, and FP5 and the step-type structures Sa, Sb, Sc, and Sd of the second region A2 and the third region B are covered by the second upper insulating layer 125. Top surfaces of the first and second upper insulating layers 120 and 125 may be on a same plane, e.g., level with each other.

Referring to FIG. 15C, the first peripheral contact via structures 183a, 183a′, and 183a″ penetrating through the second upper insulating layer 125, the mold structures 112′ and 114′, and the intermediate insulating layer 104 in the second region A2 are formed. The first peripheral contact via structures 183a, 183a′, and 183a″ may be formed in the flat structures FP2, FP3, and FP4.

The first peripheral contact via structures 183a, 183a′, 183a″ may be formed by selectively etching the second upper insulating layer 125, the mold structure 112′ and 114′, and the intermediate insulating layer 104. The first peripheral contact via structures 183a, 183a′, and 183a″ may respectively have different thicknesses of the second upper insulating layer 125 and the mold structures 112′ and 114′ that are etched.

The second peripheral contact via structure 183b penetrating through the second upper insulating layer 125 and the intermediate insulating layer 104 in the third region B is formed. The second peripheral contact via structure 183b is formed by selectively etching the second upper insulating layer 125 and the intermediate insulating layer 104.

In the first region A1, the third peripheral contact via structure 183c penetrating through the first upper insulating layer 120, the mold structures 112′ and 114′, and the intermediate insulating layer 104 is formed. The third peripheral contact via structure 183c is formed by selectively etching the first upper insulating layer 120, the mold structures 112′ and 114′, and the intermediate insulating layer 104.

The first peripheral contact via structures 183a, 183a′, and 183a″, the second peripheral contact via structure 183b, and the third peripheral contact via structures 183c are simultaneously formed. When the first peripheral contact via structures 183a, 183a′, and 183a″, the second peripheral contact via structures 183b, and the third peripheral contact via structures 183c are simultaneously formed, etched material layers being selectively etched are different, and thus, difference between critical dimensions of the first peripheral contact via structures 183a, 183a′, and 183a″, the second peripheral contact via structure 183b, and the third peripheral contact via structures 183c may cause decrease in reliability. Accordingly, embodiments may improve the reliability by specifically configuring the different first critical dimensions of the first peripheral contact via structures 183a, 183a′, and 183a″, the second critical dimension of the second peripheral contact via structure 183b, and the third peripheral contact via structure 183c according to thicknesses and types of the etched material layers.

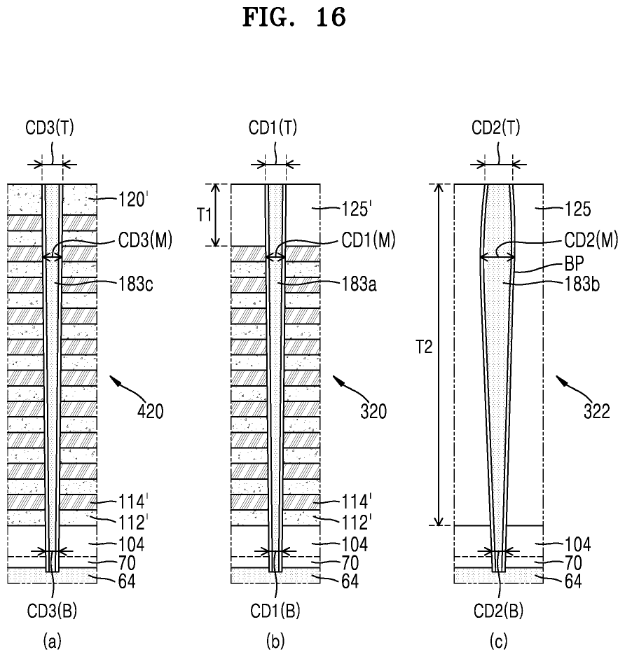

FIG. 16 is a conceptual cross-sectional view of shapes of peripheral contact via structures that may be arranged in through regions of a three-dimensional semiconductor memory device according to an embodiment.

In detail, (b) of FIG. 16 corresponds to the first peripheral contact via structure 183a formed in the first through region 320 of the second region A2, as described above. The first through region 320 may include the mold structures 112′ and 114′ and the second upper insulating layer 125′ having the thickness T1. The first peripheral contact via structure 183a may penetrate through the second upper insulating layer 125′, the mold structures 112′ and 114′, the intermediate insulating layer 104, and the lower insulating layer 70, and may be connected to the upper peripheral wiring 64.

A first critical dimension of the first peripheral contact via structure 183a may be CD1. The first critical dimension CD1 may include a first bottom critical top dimension CD1(B) at a bottom portion of the first peripheral contact via structure 183a, a first middle critical dimension CD1(M) of a middle portion of the first peripheral contact via structure 183a, and a first top critical dimension CD1(T) of a top portion of the first peripheral contact via structure 183a. For example, as illustrated in FIG. 16, the first bottom critical top dimension CD1(B) may be smaller than the first middle critical dimension CD1(M), and the first middle critical dimension CD1(M) may be smaller than the first top critical dimension CD1(T). For example, as illustrated in FIG. 16, the first top critical dimension CD1(T) may be measured as a width, e.g., diameter, along a horizontal direction at a topmost surface of the first peripheral contact via structure 183a.

Further, (c) of FIG. 16 corresponds to the second peripheral contact via structure 183b formed in the second through region 322 of the third region B. The second through region 322 may include the second upper insulating layer 125 having the thickness T2. The second peripheral contact via structure 183b may penetrate through the second upper insulating layer 125, the intermediate insulating layer 104, and the lower insulating layer 70, and may be connected to the upper peripheral wiring 64. For example, as illustrated in FIG. 16, a total thickness, e.g., height, of the second peripheral contact via structure 183b along the vertical direction, e.g., from a topmost surface to a bottommost surface, may equal to a total thickness, e.g., height, of the first peripheral contact via structure 183a along the vertical direction, e.g., from a topmost surface to a bottommost surface.

A second critical dimension of the second peripheral contact via structure 183b may be CD2. The second critical dimension CD2 may include a second bottom critical dimension CD2(B) of a bottom portion of the second peripheral contact via structure 183b, a second middle critical dimension CD2(M) of a middle portion of the second peripheral contact via structure 183b, and a second top critical dimension CD2(T) of a top portion of the second peripheral contact via structure 183b. As the second peripheral contact via structure 183b includes a bowing portion BP in the middle portion, the second middle critical dimension CD2(M) may be greater than the second top critical dimension CD2(T), and the second top critical dimension CD2(T) may be greater than the second bottom critical dimension CD2(B). For example, as illustrated in FIG. 16, the second top critical dimension CD2(T) may be measured as a width, e.g., diameter, along a horizontal direction at a topmost surface of the second peripheral contact via structure 183b.

In addition, (a) of FIG. 16 corresponds to the third peripheral contact via structure 183c formed in the third through region 420 of the first region A1. The third through region 420 may include the mold structures 112′ and 114′. The third peripheral contact via structure 183c may penetrate the first upper insulating layer 120′, the mold structures 112′ and 114′, the intermediate insulating layer 104, and the lower insulating layer 70 and may be connected to the upper peripheral wiring 64. For example, as illustrated in FIG. 16, a total thickness, e.g., height, of the third peripheral contact via structure 183c along the vertical direction, e.g., from a topmost surface to a bottommost surface, may equal to a total thickness of each of the first and second peripheral contact via structures 183a and 183b.

A third critical dimension of the third peripheral contact via structure 183c may be CD3. The third critical dimension CD3 may include a third bottom critical dimension CD3(B) of a bottom portion of the third peripheral contact via structure 183c, a third middle critical dimension CD3(M) of a middle portion of the third peripheral contact via structure 183c, and a third top critical dimension CD3(T) of a top portion of the third peripheral contact via structure 183c. For example, as illustrated in FIG. 16, the third top critical dimension CD3(T) may be measured as a width, e.g., diameter, along a horizontal direction at a topmost surface of the third peripheral contact via structure 183c. For example, the first middle critical dimension CD1(M), the second middle critical dimension CD2(M), and the third middle critical dimension CDM(3) may indicate greatest critical dimensions in the middle portions from top to bottom.

As described above, the first critical dimension CD1 of the first peripheral contact via structure 183a, the second critical dimension CD2 of the second peripheral contact via structure 183b, and the third critical dimension CD3 of the third peripheral contact via structure 183c are differently configured according to material layers included in the first through region 320, the second through region 322, and the third through region 420. For example, as illustrated in FIG. 16, the first through third peripheral contact via structure 183a through 183c may have first through third top critical dimension CD1(T) through CD3(T) that are different from each other, e.g., via masks with different diameters, in accordance with their regions on the substrate, e.g., in accordance with the combination of stacked layers through which each of the peripheral contact via structure penetrates.

In some embodiments, the second critical dimension CD2 is configured to be greater than the first critical dimension CD1. The third critical dimension CD3 is configured to be smaller than the first critical dimension CD1 and the second critical dimension CD2. Comparison between the first critical dimension CD1, the second critical dimension CD2, and the third critical dimension CD3 may be confirmed according to comparison between the first top critical dimension CD1(T), the second top critical dimension CD2(T), and the third top critical dimension CD3(T). That is, the differences between the first through third critical dimensions CD1 through CD3 are determined according to the differences between the first through third top critical dimension CD1(T) through CD3(T).

As a result, in embodiments, the skew defined by the difference between the first critical dimension CD1, the second critical dimension CD2, and the third critical dimension CD3 may be differently configured according to the material layers included in the first through region 320, the second through region 322, and the third through region 420. In some embodiments, the skew defined by the difference between the first critical dimension CD1, the second critical dimension CD2, and the third critical dimension CD3 may be adjusted to be 10% or smaller with reference to the first critical dimension CD1, the second critical dimension CD2, and the third critical dimension CD3. Details thereof will be described later. For example, the skew may be adjusted to be 10% or smaller between any two of the first critical dimension CD1, the second critical dimension CD2, and the third critical dimension CD3.

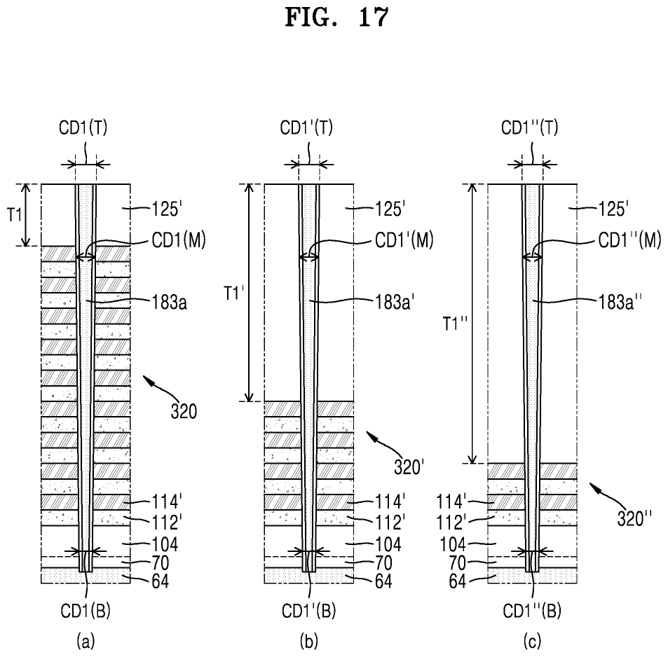

FIG. 17 is a conceptual cross-sectional view of a shape of a peripheral contact via structure that may be arranged in through regions of the three-dimensional memory device according to an embodiment.

In detail, as described above, (a) of FIG. 17 corresponds to the first peripheral contact via structure 183a formed in the first through region 320 of the second region A2. The first through region 320 may include the mold structures 112′ and 114′ and the second upper insulating layer 125′ having the thickness T1.

Further, (b) of FIG. 17 corresponds to the first peripheral contact via structure 183a′ formed in the first through region 320′ of the second region A2. The first through region 320′ may include the mold structures 112′ and 114′ and the second upper insulating layer 125′ having the thickness T3.

In addition, (c) of FIG. 17 corresponds to the first peripheral contact via structure 183a″ formed in the first through region 320″ of the second region A2. The first through region 320″ may include the mold structures 112′ and 114′ and the second upper insulating layer 125′ of the T3 thickness.

The first peripheral contact via structures 183a, 183a′, and 183a″ may penetrate through the second upper insulating layer 125′, the mold structures 112′ and 114′, the intermediate insulating layer 104, and the lower insulating layer 70, and be connected to the upper peripheral wiring 64. The first peripheral contact via structures 183a, 183a′, and 183a″ may have first critical dimensions CD1, CD1′, and CD1″. The first critical dimensions CD1, CD1′, and CD1″ may include first bottom critical dimensions CD1(B), CD1′(B), and CD1″(B) of bottom portions of the first peripheral contact via structures 183a, 183a′, and 183a″, first middle critical dimensions CD1(M), CD1′(M), and CD1″(M) of middle portions of the first peripheral contact via structures 183a, 183a′, and 183a″, and first top critical dimensions of CD1(T), CD1′(T), and CD1″(T) of top portions of the first peripheral contact via structures 183a, 183a′, and 183a″.

As described above, the first critical dimensions CD1, CD1′, and CD1″ of the first peripheral contact via structure 183a, 183a′, and 183a″ are differently configured according to thicknesses of the material layers included in the first through regions 320, 320′, and 320″, e.g., the thickness of the second upper insulating layer 125′.

In some embodiment, the first critical dimension CD1″ is configured to be greater than the first critical dimension CD1. The first critical dimension CD1″ is configured to be smaller than the first critical dimension CD1 and the first critical dimension CD1′. Comparison between the first critical dimensions CD1, CD1′, and CD1″ may be confirmed according to comparison between the first top critical dimensions CD1(T), CD1′(T), and CD1″(T).

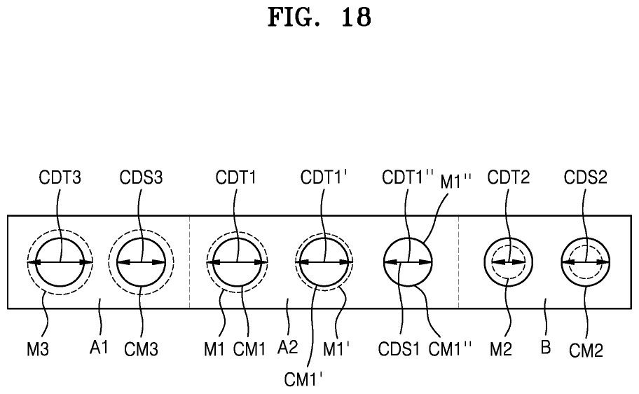

FIG. 18 is a top-plan view of a mask layout for forming peripheral contact via structures of a three-dimensional semiconductor memory device according to an embodiment.

In detail, the mask patterns CM1, CM1′, CM1″, CM2, and CM3 (i.e., indicated by a solid line in FIG. 18) of the peripheral contact via structures of the Comparative Example are arranged to have same critical dimensions CDS1, CDS2, and CDS3 in all of the first region A1, the second region A2, and the third region B. In other words, the critical dimensions CDS1 in the second regions A2 are arranged to be identical to the critical dimensions CDS2 and CDS3 in the first region A1 and the third region B.

On the contrary, the mask patterns M1, M1′, M1“, M2, and M3 (i.e., indicated by a dashed line in FIG. 18) of the peripheral contact via structures are arranged to have different critical dimensions CDT1, CDT1′, CDT1”, CDT2, and CDT3 according to the first region A1, the second region A2, and the third region B. In other words, the critical dimensions CDT1 and CDT1′ of the mask patterns M1 and M1′ of the second region A2 may be greater than the critical dimensions CDT1″ of the mask patterns M1″ of the second region A2.

The critical dimensions CDT3 of the mask patterns M3 of the first region A1 may be greater than the critical dimensions CDT1, CDT1′, and CDT1″ of the mask patterns M1, M1′, and M1″ of the second region A2. The critical dimensions CDT2 of the mask patterns M2 of the third region B may be smaller than the critical dimensions CDT1, CDT1′, and CDT1″ of the mask patterns M1, M1′, and M1″ of second region A2.

In this case, the peripheral contact via structures in embodiments may be configured to have different critical dimensions according to types or thicknesses of the material layers in the through regions of the first region A1, the second region A2, and the third region B, and the peripheral contact via structures may be formed with more reliability.

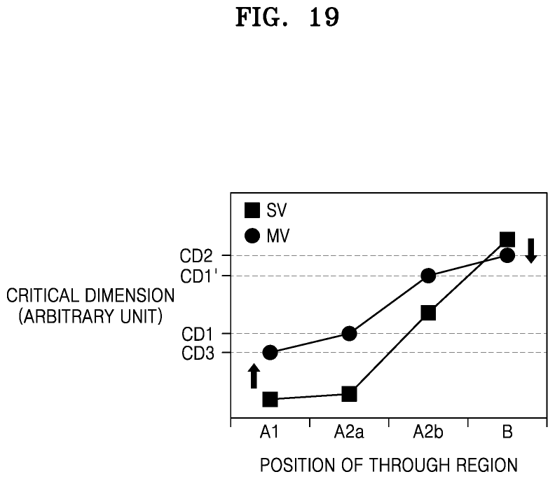

FIG. 19 is a diagram for describing differences in critical dimensions of peripheral contact via structures according to regions in a three-dimensional semiconductor memory device according to an embodiment.

In detail, referring to FIG. 19, reference numeral SV represents a case in which the peripheral contact via structures are formed by using the mask patterns CM1, CM1′, CM1″, CM2, and CM3 in the Comparative Example shown in FIG. 18. Reference numeral MV represents a case in which the peripheral contact via structures are formed by using the mask patterns M1, M1′, M2, and M3 shown in FIG. 18.

As shown in FIG. 19, a critical dimension CD3 of the peripheral contact via structure in the first region A1 is greater than that of the corresponding Comparative Example. It is also shown that the critical dimension CD2 of the peripheral contact via structure is smaller than that of corresponding Comparative Example. Therefore, it may be known that a difference between critical dimension of the peripheral contact via structures in the first region A1 and the third region B decreases.

In a quantitative sense, it may be desirable to adjust the skew, which is defined by the difference between the second critical dimension CD2 of the peripheral contact via structure in the third region B and the third critical dimension CD3 of the peripheral contact via structure in the first region A1 to be 10% or smaller with reference to the second critical dimension CD2 or the first critical dimension CD1 and CD1′.

In addition, it may be desirable to adjust the skew, which is defined by the difference between the first critical dimensions CD1 and CD1′ of the peripheral contact via structures in the second regions A2a and A2b and the second critical dimension CD2 of the peripheral contact via structure in the third region B to be 10% or smaller with reference to the first critical dimensions CD1 and CD1′ or the second critical dimension CD2.

By way of summation and review, according to embodiments, a three-dimensional semiconductor memory device includes peripheral contact via structures that have critical dimensions (CDs) configured differently according to regions. Accordingly, the three-dimensional semiconductor memory device may stably include the peripheral contact via structure according to regions. The skew defined by a difference between two critical dimensions may be adjusted to be 10% or smaller with reference to the critical dimensions.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A three-dimensional semiconductor memory device, comprising:
a peripheral circuit structure;
a cell array structure above the peripheral circuit structure; and
peripheral contact via structures connecting the cell array structure to the peripheral circuit structure, the peripheral contact via structures including:
a first peripheral contact via structure in a first through region in the peripheral circuit structure, and
a second peripheral contact via structure in a second through region in the peripheral circuit structure, the second through region being spaced apart from the first through region above the peripheral circuit structure, and a difference between a second critical dimension of the second peripheral contact via structure and a first critical dimension of the first peripheral contact via structure being differently configured according to material layers included in the second through region and the first through region.

2. The three-dimensional semiconductor memory device as claimed in claim 1, wherein the difference between the second critical dimension of the second peripheral contact via structure and the first critical dimension of the first peripheral contact via structure is 10% or less with reference to the first critical dimension or the second critical dimension.

3. The three-dimensional semiconductor memory device as claimed in claim 1, wherein:
the first critical dimension includes a first bottom critical dimension of a bottom portion of the first peripheral contact via structure, a first middle critical dimension of a middle portion of the first peripheral contact via structure, and a first top critical dimension of a top portion of the first peripheral contact via structure,
the second critical dimension includes a second bottom critical dimension of a bottom portion of the second peripheral contact via structure, a second middle critical dimension of a middle portion of the second peripheral contact via structure, and a second top critical dimension of a top portion of the second peripheral contact via structure, and
the difference between the second critical dimension of the second peripheral contact via structure and the first critical dimension of the first peripheral contact via structure is defined by a difference between the second top critical dimension and the first top critical dimension.

4. The three-dimensional semiconductor memory device as claimed in claim 3, wherein the second peripheral contact via structure includes a bowing portion in the middle portion of the second peripheral contact via structure, the second middle critical dimension being greater than the second top critical portion.

5. The three-dimensional semiconductor memory device as claimed in claim 1, wherein:
the first through region includes a mold structure and a first upper insulating layer above the mold structure, the mold structure including a plurality of interlayer insulating layers and mold insulating layers that are stacked together, and
the second through region includes a second upper insulating layer, a total thickness of the second through region being a same as that of the first through region.

6. The three-dimensional semiconductor memory device as claimed in claim 1, wherein:
the first through region includes a mold structure having interlayer insulating layers and mold insulating layers, and
the second through region includes an insulating layer and has a same thickness as that of the first through region.

7. The three-dimensional semiconductor memory device as claimed in claim 1, wherein:
the cell array structure includes a cell array region, an extending region electrically connected to the cell array region, and a peripheral region at one side of the extending region,
the first through region is in the extending region, and
the second through region is in the peripheral region.

8. The three-dimensional semiconductor memory device as claimed in claim 1, wherein:
the cell array structure includes a cell array region, an extending region electrically connected to the cell array region, and a peripheral region at one side of the extending region,
the first through region is in the extending region, and
the second through region is in the cell array region.

9. The three-dimensional semiconductor memory device as claimed in claim 8, wherein the extending region includes a step-type structure having a width decreasing away from the peripheral circuit structure, and a flat structure having a same width above the peripheral circuit structure.

10. A three-dimensional semiconductor memory device, comprising:
a peripheral circuit structure;
a cell array structure above the peripheral circuit structure; and
peripheral contact via structures connecting the cell array structure to the peripheral circuit structure, the peripheral contact via structures including:
a first peripheral contact via structure in a first through region of the peripheral circuit structure,
a second peripheral contact via structure in a second through region, the second through region being spaced apart from the first through region in a first direction above the peripheral circuit structure, and
a third peripheral contact via structure in a third through region, the third through region being spaced apart from the first through region in a second direction,
wherein the first peripheral contact via structure, the second peripheral contact via structure, and the third peripheral contact via structure respectively have a first critical dimension, a second critical dimension, and a third critical dimension, differences between the first critical dimension, the second critical dimension, and the third critical dimension being differently configured according to material layers included in the first through region, the second through region, and the third through region.

11. The three-dimensional semiconductor memory device as claimed in claim 10, wherein a difference between two of the first critical dimension, the second critical dimension, and the third critical dimension is 10% or less with reference to the two of the first critical dimension, the second critical dimension, and the third critical dimension.

12. The three-dimensional semiconductor memory device as claimed in claim 10, wherein:
the first through region includes a mold structure having insulating layers and mold insulating layers, and a first upper insulating layer above the mold structure,
the second through region includes a second upper insulating layer and has a same total thickness as that of the first through region, and
the third through region includes the mold structure and has a same total thickness as those of the first through region and the second through region.

13. The three-dimensional semiconductor memory device as claimed in claim 10, wherein the cell array structure includes:
a cell array region above the peripheral circuit structure;
an extending region electrically connected to the cell array region and at one side of the cell array region; and
a peripheral region at one side of the extending region.

14. The three-dimensional semiconductor memory device as claimed in claim 13, wherein the first through region is in the extending region, the second through region is in the peripheral region, and the third through region is in the cell array region.

15. The three-dimensional semiconductor memory device as claimed in claim 13, wherein;
the extending region includes a step-type structure having a width decreasing away from the peripheral circuit structure, and a flat structure having a same width above the peripheral circuit structure, and
the first through region is in the flat structure.

16. A three-dimensional semiconductor memory device, comprising:
a peripheral circuit structure on a substrate;
a semiconductor layer above the peripheral circuit structure, the semiconductor layer including intermediate insulating layers spaced apart from one another;
a cell array structure above the semiconductor layer and the intermediate insulating layers, the cell array structure including a cell array region, an extending region at one side of the cell array region and connected to the cell array region, and a peripheral region at one side of the extending region; and
peripheral contact via structures penetrating through the cell array structure and the intermediate insulating layers, and electrically connected to the peripheral circuit structure,
wherein the peripheral contact via structures include:
a first peripheral contact via structure in a first through region, the first through region being in the extending region,
a second peripheral contact via structure in a second through region, the second through region being in the peripheral region and spaced apart from the first through region in first a direction, and
a third peripheral contact via structure in a third through region, the third through region being in the cell array region and spaced apart from the first through region in a second direction, and
wherein the first peripheral contact via structure, the second peripheral contact via structure, and the third peripheral contact via structure respectively have a first critical dimension, a second critical dimension, and a third critical dimension, differences between the first critical dimension, the second critical dimension, and the third critical dimension being differently configured according to material layers included in the first through region, the second through region, and the third through region.

17. The three-dimensional semiconductor memory device as claimed in claim 16, wherein a difference between the second critical dimension and the third critical dimension is 10% or less with reference to the second critical dimension or the third critical dimension.

18. The three-dimensional semiconductor memory device as claimed in claim 16, wherein:
the first through region includes a mold structure having interlayer insulating layers and mold insulating layers, and a first upper insulating layer above the mold structure,
the second through region includes a second upper insulating layer and has a same total thickness as that of the first through region, and
the third through region includes the mold structure and has a same total thickness as those of the first through region and the second through region.

19. The three-dimensional semiconductor memory device as claimed in claim 16, wherein:
the second critical dimension includes a second bottom critical dimension of a bottom portion of the second peripheral contact via structure, a second middle critical dimension of a middle portion of the second peripheral contact via structure, and a second top critical dimension of a top portion of the second peripheral contact via structure, and
the second peripheral contact via structure includes a bowing portion in the middle portion of the second peripheral contact via structure, the second middle critical dimension being greater than the second top critical dimension.

20. The three-dimensional semiconductor memory device as claimed in claim 16, wherein:
the extending region includes a first step-type structure having a width decreasing away from the peripheral circuit structure;
a second step-type structure apart from the first step-type structure; and
a flat structure between the first step-type structure and the second step-type structure, the first through region being in the flat structure.
